(19) United States
(12) Patent Application Publication
(10) Pub. No.: US 2025/0318112 A1
(43) Pub. Date: Oct. 9, 2025

(54) SEMICONDUCTOR STRUCTURE AND METHOD OF FORMING THE SAME

(71) Applicant: NANYA TECHNOLOGY CORPORATION, New Taipei city (TW)

(72) Inventor: Ying-Cheng CHUANG, New Taipei City (TW)

(21) Appl. No.: 18/628,587

(22) Filed: Apr. 5, 2024

(51) Int. Cl. H10B 12/00

(52) U.S. Cl. CPC H10B 12/50; H10B 12/09; H10B 12/34

(57) ABSTRACT

A semiconductor structure includes a substrate, a gate dielectric layer, and a gate structure. The substrate has an array area and a peripheral area adjacent to the array area, wherein the peripheral area of the substrate has a recess. The gate dielectric layer is located on a surface of the recess. The gate structure is located in the recess and includes a first work function layer and a second work function layer. The first work function layer is located on the gate dielectric layer. The second work function layer is located on the first work function layer and surrounded by the first work function layer, wherein the first work function layer is located between the second work function layer and the gate dielectric layer, and a work function of the first work function layer is different from that of the second work function layer.

### BACKGROUND

### Field of Invention

The present disclosure relates to a semiconductor structure and a method of forming the semiconductor structure.

### Description of Related Art

With the development of modern technology, integration circuits and electrical products have been pushed for size reductions to match the trend of high integration and high density. In a traditional planar trench capacitor DRAM, the source, gate, and drain of a MOS transistor are horizontally located on the top surface of the substrate. The distance between the source and the drain determines the channel length of the gate.

Although the small device (e.g., transistor) can help chip size shrinkage, the small channel length will induce leakage issue. In addition, a dual work function process may improve gate induced drain leakage (GIDL), but the resistance of a low word function (e.g., polysilicon) is high.

### SUMMARY

According to some embodiments of the present disclosure, a semiconductor structure includes a substrate, a gate dielectric layer, and a gate structure. The substrate has an array area and a peripheral area adjacent to the array area, wherein the peripheral area of the substrate has a recess. The gate dielectric layer is located on a surface of the recess. The gate structure is located in the recess and includes a first work function layer and a second work function layer. The first work function layer is located on the gate dielectric layer. The second work function layer is located on the first work function layer and surrounded by the first work function layer, wherein the first work function layer is located between the second work function layer and the gate dielectric layer, and a work function of the first work function layer is different from a work function of the second work function layer.

In some embodiments, the work function of the second work function layer is higher than the work function of the first work function layer.

In some embodiments, a material of the first work function layer includes polysilicon, and a material of the second work function layer includes titanium nitride.

In some embodiments, the semiconductor structure further includes a first dielectric layer, a second dielectric layer, and an insulating layer. The first dielectric layer is located on a top surface of the substrate. The second dielectric layer is located on the first dielectric layer. The insulating layer is located on the second dielectric layer, wherein a top surface of the second work function layer and a top surface of the first work function layer are higher than a bottom surface of the insulating layer.

In some embodiments, the top surface of the second work function layer and the top surface of the first work function layer are higher than a top surface of the second dielectric layer.

In some embodiments, the gate dielectric layer extends to a sidewall of the insulating layer sequentially along a sidewall of the first dielectric layer and a sidewall of the second dielectric layer.

In some embodiments, the first work function layer has a portion between the second work function layer and the insulating layer.

In some embodiments, the first work function layer has a portion between the second work function layer and the second dielectric layer.

In some embodiments, the first work function layer has a portion between the second work function layer and the first dielectric layer.

In some embodiments, the array area of the substrate has a trench, and the second dielectric layer extends into the trench of the array area of the substrate.

In some embodiments, a depth of the recess the peripheral area of the substrate is less than a depth of the trench of the array area of the substrate.

In some embodiments, the array area of the substrate includes a word line structure in the trench and surrounded by the second dielectric layer.

In some embodiments, the word line structure includes a titanium nitride layer and a polysilicon layer above and aligned with the titanium nitride layer in a vertical direction.

According to some embodiments of the present disclosure, a method of forming a semiconductor structure includes forming a recess in a peripheral area of a substrate; forming a gate dielectric layer on a surface of the recess; forming a first work function layer in the recess and on the gate dielectric layer; and forming a second work function layer in the recess and on the first work function layer, wherein the first work function layer and the second work function layer define a gate structure, the second work function layer is surrounded by the first work function layer, the first work function layer is located between the second work function layer and the gate dielectric layer, and a work function of the first work function layer is different from a work function of the second work function layer.

In some embodiments, the method of forming the semiconductor structure further includes forming a first dielectric layer on a top surface of the substrate; forming a second dielectric layer on the first dielectric layer; and forming an insulating layer on the second dielectric layer.

In some embodiments, the method of forming the semiconductor structure further includes forming an oxide layer to cover the insulating layer; and etching the oxide layer to form a remaining portion of the oxide layer on the insulating layer on the peripheral area of the substrate.

In some embodiments, the method of forming the semiconductor structure further includes forming a hard mask layer to cover the remaining portion of the oxide layer and the insulating layer; etching back the hard mask layer to expose the remaining portion of the oxide layer; etching the remaining portion of the oxide layer and the insulating layer below the remaining portion of the oxide layer to form an opening, wherein a portion of the substrate is exposed through the opening; and removing the hard mask layer.

In some embodiments, forming the recess in the peripheral area of the substrate includes etching the portion of the substrate exposed through the opening by using the insulating layer as a mask.

In some embodiments, the method of forming the semiconductor structure further includes forming the gate dielectric layer on a sidewall of the first dielectric layer, a sidewall of the second dielectric layer, and a sidewall of the insulating layer; forming the first work function layer on a top surface of the insulating layer and the gate dielectric layer that is on the sidewall of the first dielectric layer, the sidewall of the second dielectric layer, and the sidewall of the insulating layer; and forming the second work function layer along the first work function layer.

In some embodiments, the method of forming the semiconductor structure further includes etching the second work function layer and the first work function layer in sequence to form the gate structure.

In the aforementioned embodiments of the present disclosure, since the gate structure including first work function layer and the second work function layer is located in the recess of the peripheral area of the substrate, the recess channel of the semiconductor structure can improve leakage issue. In addition, due to the second work function layer located on and surrounded by the first work function layer and the work function of the first work function layer different from the work function of the second work function layer, the semiconductor structure not only can improve gate induced drain leakage (GIDL) and turn on word line fast, but also can reduce the resistance (Rs) of the gate structure (e.g., the combination of the first and second work function layers).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor structure according to some embodiments of the present disclosure.

FIG. 2 is a flow chart of a method of forming a semiconductor structure according to some embodiments of the present disclosure.

FIGS. 3 to 11 are cross-sectional views at intermediate stages of a method of forming a semiconductor structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

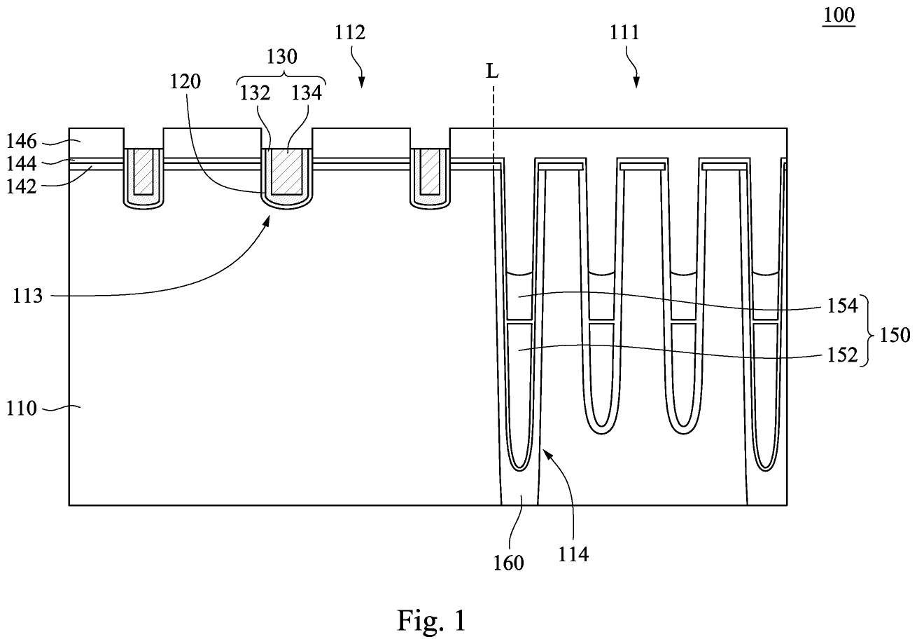

FIG. 1 is a cross-sectional view of a semiconductor structure 100 according to some embodiments of the present disclosure. As shown in FIG. 1, the semiconductor structure 100 includes a substrate 110, a gate dielectric layer 120, and a gate structure 130. The substrate 110 has an array area 111 and a peripheral area 112 adjacent to the array area 111. The array area 111 is located at the right side of a dashed line L, and the peripheral area 112 is located at the left side of the dashed line L. The peripheral area 112 of the substrate 110 has a recess 113. The substrate 110 may be a semiconductor substrate, such as a silicon wafer. For example, the material of the substrate 110 may include silicon. The gate dielectric layer 120 is located on the surface of the recess 113, such as the bottom and the sidewall of the recess 113. The material of the gate dielectric layer 120 may include oxide. The gate structure 130 is located in the recess 113 and includes a first work function layer 132 and a second work function layer 134. The first work function layer 132 is located on the gate dielectric layer 120. The second work function layer 134 is located on the first work function layer 132 and surrounded by the first work function layer 132. The first work function layer 132 is located between the second work function layer 134 and the gate dielectric layer 120, and the work function of the first work function layer 132 is different from the work function of the second work function layer 134.

In some embodiments, the work function of the second work function layer 134 is higher than the work function of the first work function layer 132. For example, the material of the first work function layer 132 may include polysilicon, and the material of the second work function layer 134 may include titanium nitride (TIN). The semiconductor structure 100 may be a dual work function recess transistor in DRAM periphery.

Specifically, since the gate structure 130 including first work function layer 132 and the second work function layer 134 is located in the recess 113 of the peripheral area 112 of the substrate 110, the recess channel of the semiconductor structure 100 can improve leakage issue. In addition, due to the second work function layer 134 located on and surrounded by the first work function layer 132 and the work function of the first work function layer 132 different from the work function of the second work function layer 134, the semiconductor structure 100 not only can improve gate induced drain leakage (GIDL) and turn on word line fast, but also can reduce the resistance (Rs) of the gate structure 130 (e.g., the combination of the first and second work function layers 132 and 134).

In addition, the semiconductor structure 100 further includes a first dielectric layer 142, a second dielectric layer 144, and an insulating layer 146. The first dielectric layer 142 is located on the top surface of the substrate 110. The second dielectric layer 144 is located on the first dielectric layer 142. The insulating layer 146 is located on the second dielectric layer 144. In some embodiments, the material of the first dielectric layer 142 may include nitride, and the material of the second dielectric layer 144 may include oxide. The material of the insulating layer 146 may include nitride for the word lines of the array area 111. In some embodiments, the top surface of the second work function layer 134 and the top surface of the first work function layer 132 are higher than the bottom surface of the insulating layer 146. In other words, the top surface of the second work function layer 134 and the top surface of the first work function layer 132 are higher than the top surface of the second dielectric layer 144. Furthermore, the top surface of the second work function layer 134 and the top surface of the first work function layer 132 may be coplanar. The gate dielectric layer 120 can extend to the sidewall of the insulating layer 146 sequentially along the sidewall of the first dielectric layer 142 and the sidewall of the second dielectric layer 144.

In some embodiments, the first work function layer 132 has a portion between the second work function layer 134 and the insulating layer 146, a portion between the second work function layer 134 and the second dielectric layer 144, and a portion between the second work function layer 134 and the first dielectric layer 142.

Moreover, the array area 111 of the substrate 110 has a trench 114, and the depth of the recess 113 the peripheral area 112 of the substrate 110 is less than the depth of the trench 114 of the array area 111 of the substrate 110. The second dielectric layer 144 extends into the trench 114 of the array area 111 of the substrate 110, and thus a portion of the second dielectric layer 144 is located on a dielectric layer 160 in the trench 114. The material of the dielectric layer 160 may be oxide. The array area 111 of the substrate 110 includes a word line structure 150 in the trench 114 and surrounded by the second dielectric layer 144. The word line structure 150 includes a titanium nitride layer 152 and a polysilicon layer 154 above and aligned with the titanium nitride layer 152 in a vertical direction.

It is to be noted that the connection relationships, the materials, and the advantages of the elements described above will not be repeated in the following description. In the following description, the method of forming the semiconductor structure 100 of FIG. 1 will be explained.

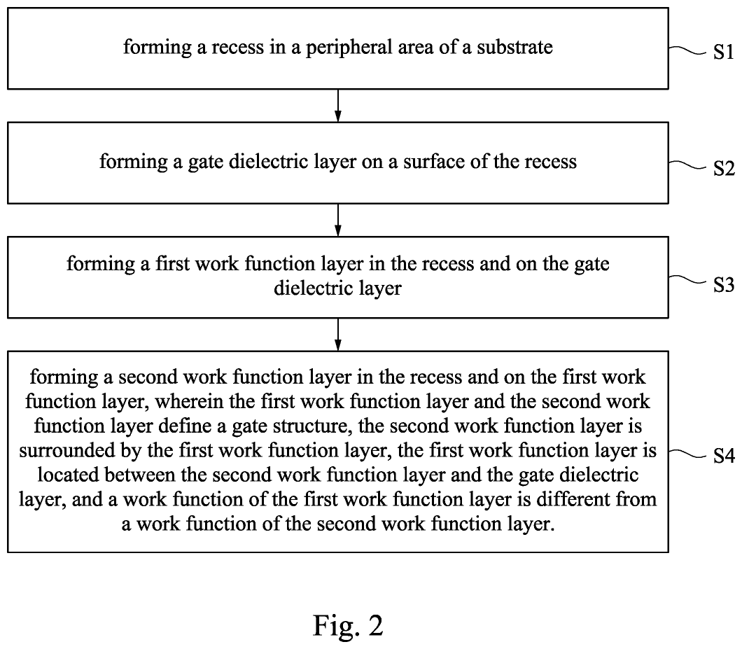

FIG. 2 is a flow chart of a method of forming a semiconductor structure according to some embodiments of the present disclosure. The method of forming the semiconductor structure includes the following steps. In step S1, a recess is formed in a peripheral area of a substrate. Thereafter, in step S2, a gate dielectric layer is formed on a surface of the recess. Afterwards, in step S3, a first work function layer is formed in the recess and on the gate dielectric layer. Subsequently, in step S4, a second work function layer is formed in the recess and on the first work function layer, wherein the first work function layer and the second work function layer define a gate structure, the second work function layer is surrounded by the first work function layer, the first work function layer is located between the second work function layer and the gate dielectric layer, and a work function of the first work function layer is different from a work function of the second work function layer.

Moreover, each of steps S1 to S4 may include plural detailed steps, the method may include other steps between step S1 and step S4, and the method may include other steps before step S1 and after step S4. In the following description, at least the aforementioned steps S1 to S4 will be described in detail.

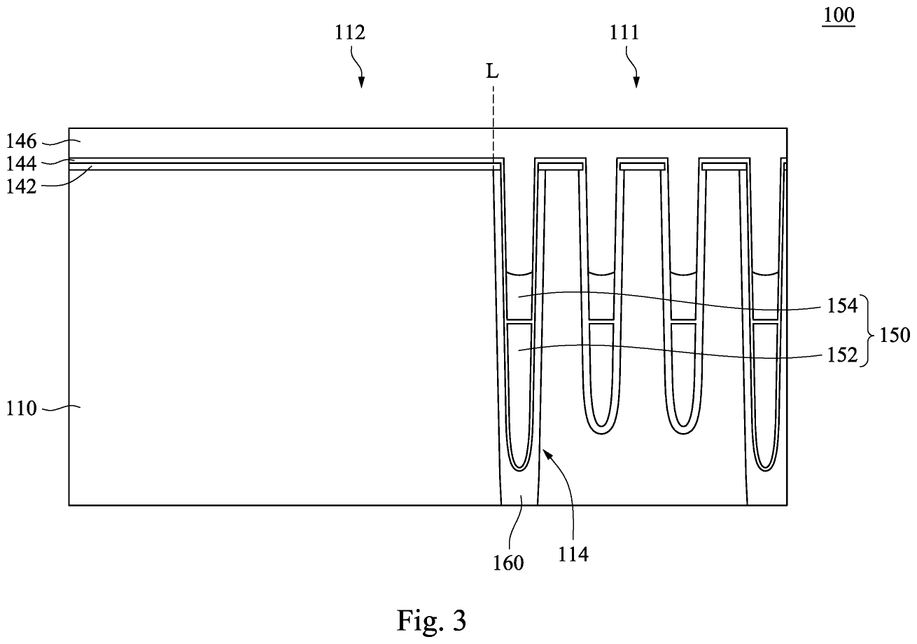

FIGS. 3 to 11 are cross-sectional views at intermediate stages of a method of forming a semiconductor structure according to some embodiments of the present disclosure. As shown in FIG. 3, the first dielectric layer 142 is formed on the top surface of the substrate 110, and the second dielectric layer 144 is formed on the first dielectric layer 142. In addition, the trench 114 is formed in the array area 111 of the substrate 110, the dielectric layer 160 is formed along the surface of the trench 114, and the second dielectric layer 144 is formed along the surface of the dielectric layer 160. Thereafter, the word line structure 150 including the titanium nitride layer 152 and the polysilicon layer 154 are formed in the trench 114 in the array area 111. The insulating layer 146 is formed on the second dielectric layer 144, and is formed to fill the trench 114 to cover the polysilicon layer 154.

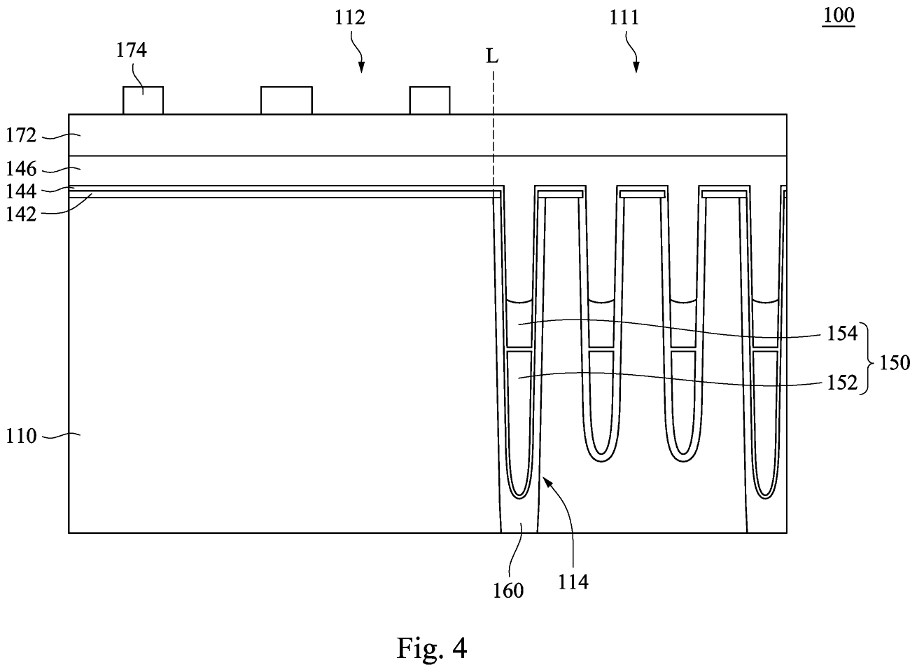

As shown in FIG. 4, after the formation of the structure of FIG. 3, an oxide layer 172 is formed to cover the insulating layer 146, and a patterned photoresist layer 174 is formed on the oxide layer 172 on the peripheral area 112 of the substrate 110. In some embodiments, the material of the oxide layer 172 includes silicon dioxide (SiO₂).

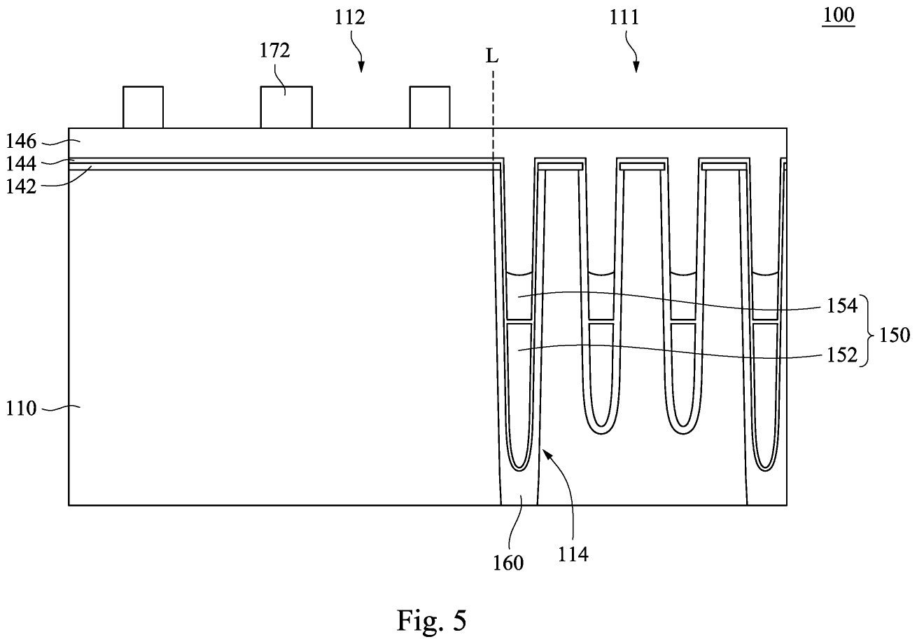

Thereafter, as shown in FIG. 5, the oxide layer 172 is etched to form the remaining portion of the oxide layer 172 on the insulating layer 146 on the peripheral area 112 of the substrate 110, and then the photoresist layer 174 on the remaining portion of the oxide layer 172 is removed.

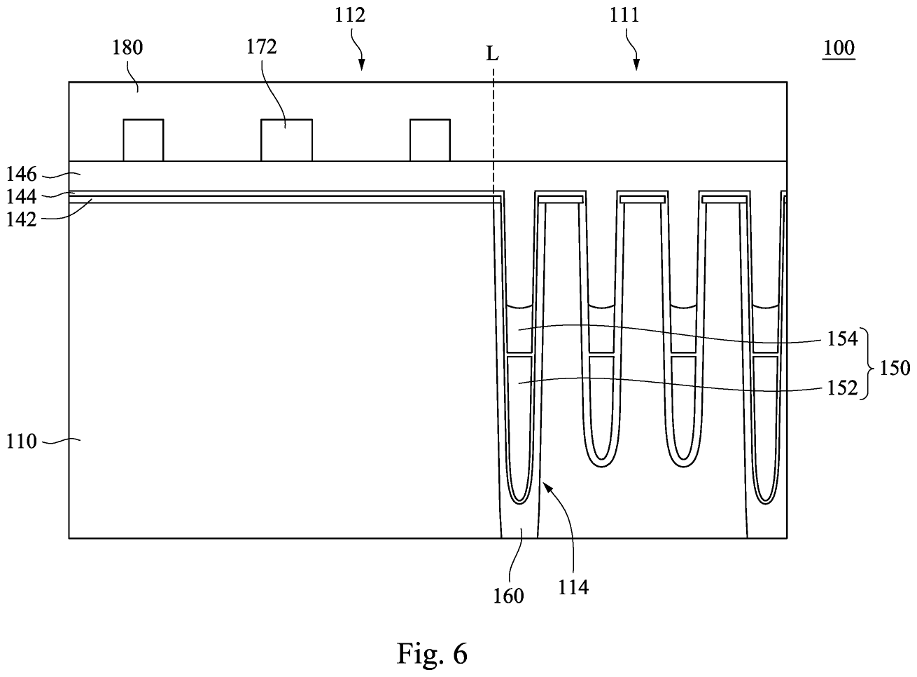

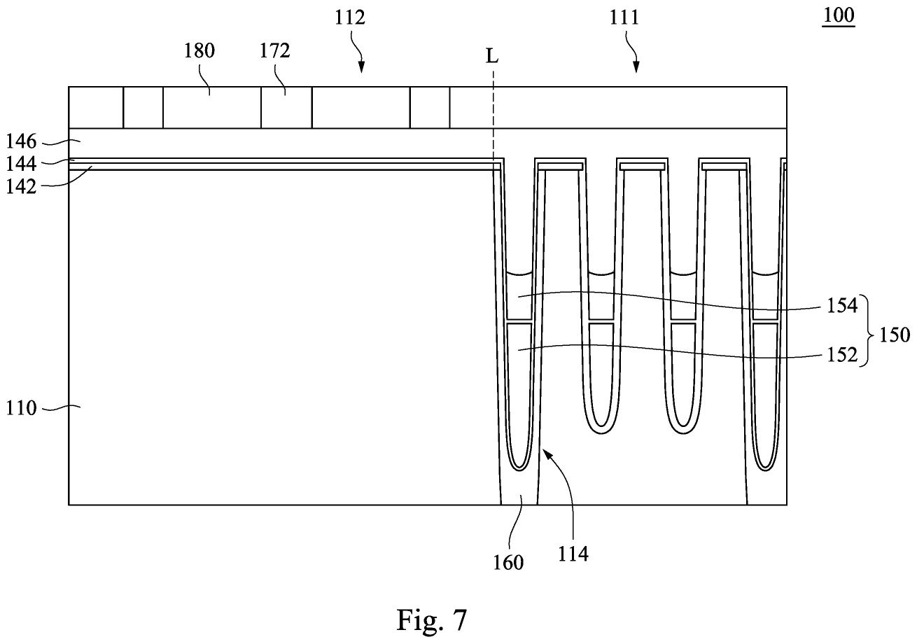

As shown in FIG. 6 and FIG. 7, a hard mask layer 180 is formed to cover the remaining portion of the oxide layer 172 and the insulating layer 146, and then the hard mask layer 180 is etched back to expose the remaining portion of the oxide layer 172. In some embodiments, the material of the hard mask layer 180 includes polymer.

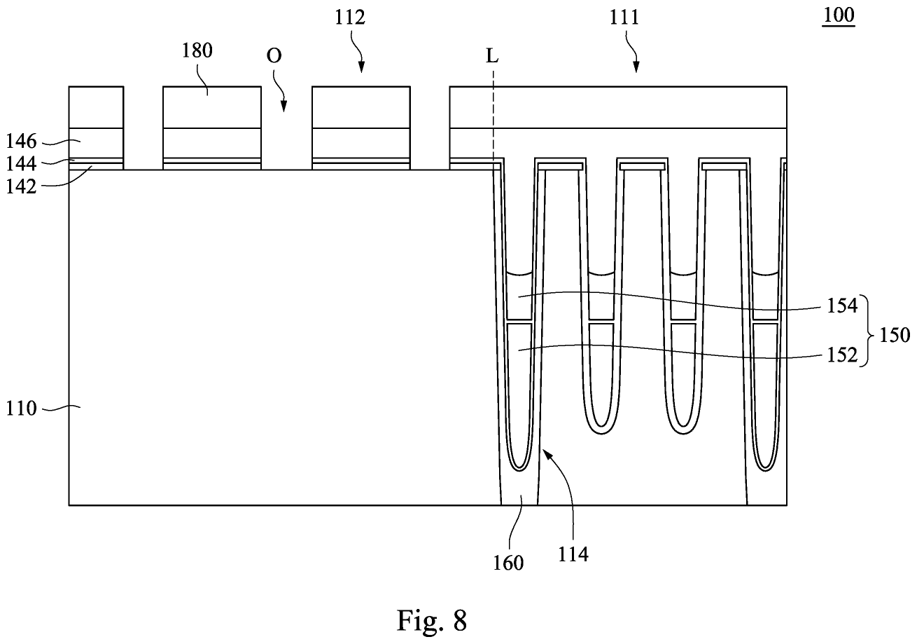

As shown in FIG. 8, after the hard mask layer 180 is etched, the remaining portion of the oxide layer 172, the insulating layer 146, the second dielectric layer 144, and the first dielectric layer 142 that are below the remaining portion of the oxide layer 172 are etched to form an opening O, such that a portion of the substrate 110 is exposed through the opening O.

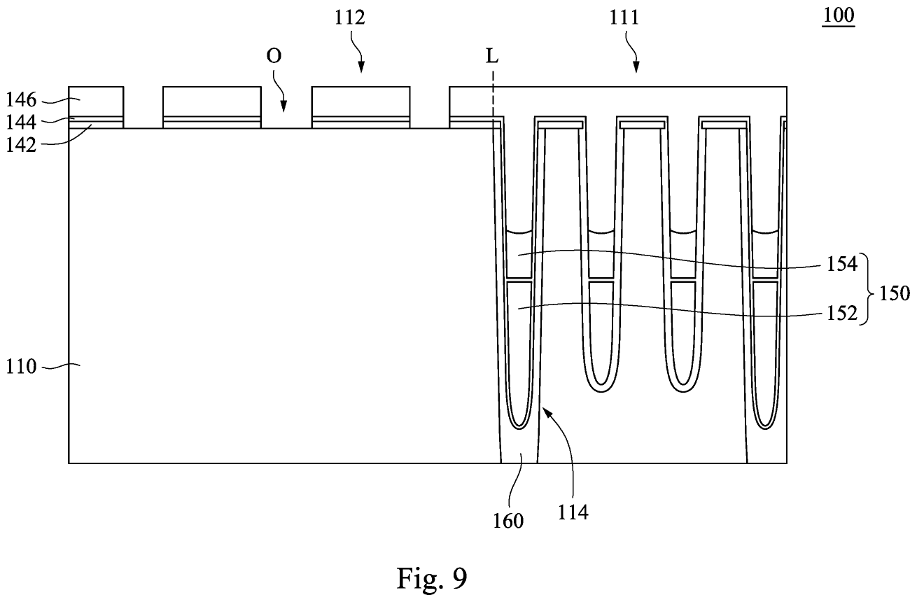

As shown in FIG. 9, after the formation of the opening O, the hard mask layer 180 is removed by photoresist strip process.

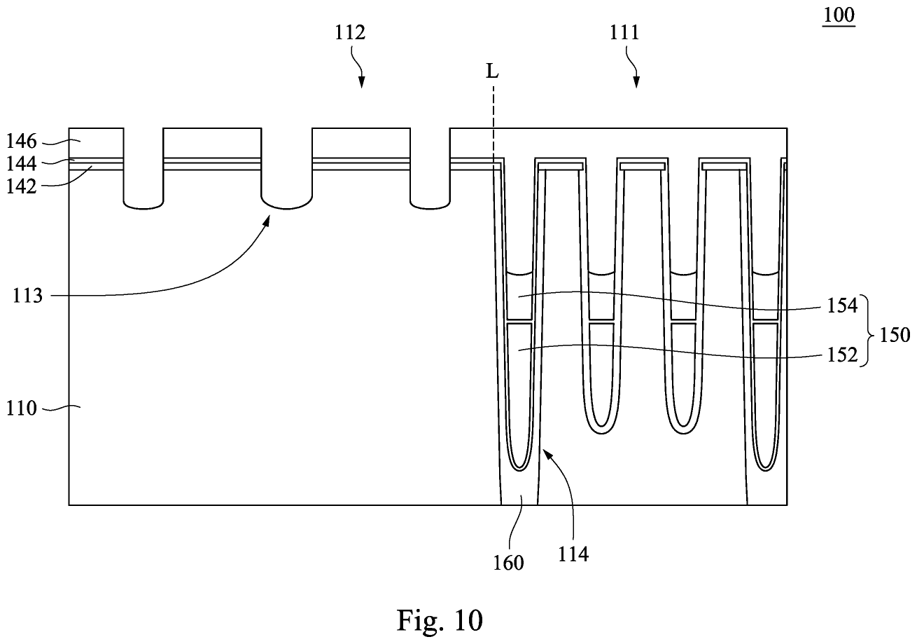

Thereafter, as shown in FIG. 10, the recess 113 is formed in the peripheral area 112 of the substrate 110. The formation of the recess 113 in the peripheral area 112 of the substrate 110 includes etching the portion of the substrate 110 exposed through the opening O by using the insulating layer 146 as a mask.

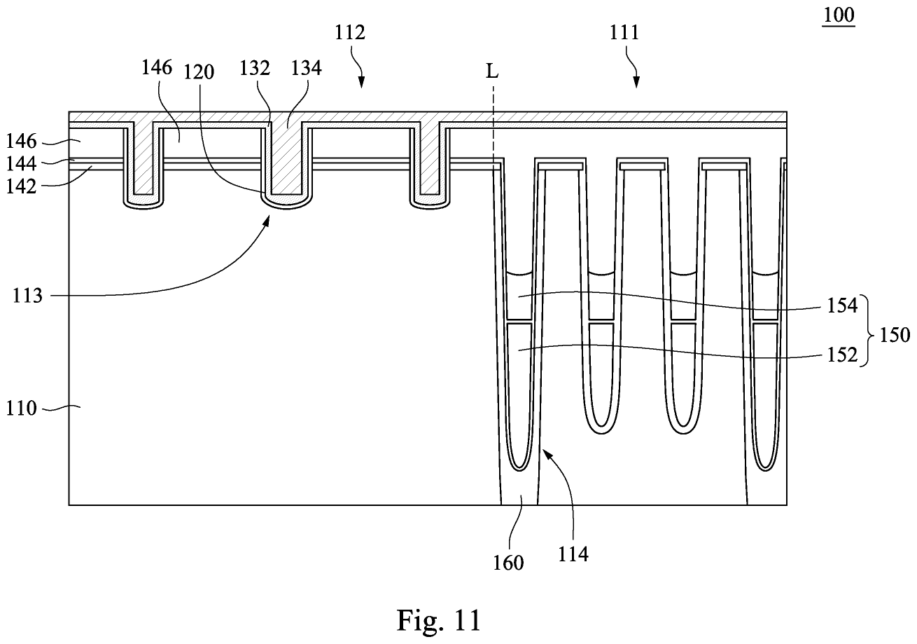

Thereafter, as shown in FIG. 11, the gate dielectric layer 120 is formed on the surface of the recess 113, the sidewall of the first dielectric layer 142, the sidewall of the second dielectric layer 144, and the sidewall of the insulating layer 146. In some embodiments, the gate dielectric layer 120 may be formed by oxidation, such as high temperature oxide (HTO) process. Other suitable processes may be used to form the gate dielectric layer 120, such as atomic layer deposition (ALD) process and in-situ steam generation (ISSG) process. Afterwards, the first work function layer 132 is formed in the recess 113 and on the gate dielectric layer 120 by polysilicon deposition. Specifically, the first work function layer 132 is formed on the gate dielectric layer 120 that is on the sidewall of the first dielectric layer 142, the sidewall of the second dielectric layer 144, and the sidewall of the insulating layer 146. During the formation of the first work function layer 132, the first work function layer 132 is also formed on the top surface of the insulating layer 146. Thereafter, the second work function layer 134 is formed in the recess 113 and on the first work function layer 132 by metal deposition. In other words, the second work function layer 134 is formed along the first work function layer 132.

After the formation of the structure of FIG. 11, the second work function layer 134 and the first work function layer 132 are etched in sequence to form the gate structure 130 of FIG. 1. As a result, the semiconductor structure 100 of FIG. 1 can be obtained. As shown in FIG. 1, the first work function layer 132 and the second work function layer 134 define the gate structure 130. The second work function layer 134 is surrounded by the first work function layer 132, and the first work function layer 132 is located between the second work function layer 134 and the gate dielectric layer 120.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate having an array area and a peripheral area adjacent to the array area, wherein the peripheral area of the substrate has a recess;
a gate dielectric layer located on a surface of the recess; and
a gate structure located in the recess and comprising:
a first work function layer located on the gate dielectric layer; and
a second work function layer located on the first work function layer and surrounded by the first work function layer, wherein the first work function layer is located between the second work function layer and the gate dielectric layer, and a work function of the first work function layer is different from a work function of the second work function layer.

2. The semiconductor structure of claim 1, wherein the work function of the second work function layer is higher than the work function of the first work function layer.

3. The semiconductor structure of claim 1, wherein a material of the first work function layer comprises polysilicon, and a material of the second work function layer comprises titanium nitride.

4. The semiconductor structure of claim 1, further comprising:
a first dielectric layer located on a top surface of the substrate;
a second dielectric layer located on the first dielectric layer; and
an insulating layer located on the second dielectric layer, wherein a top surface of the second work function layer and a top surface of the first work function layer are higher than a bottom surface of the insulating layer.

5. The semiconductor structure of claim 4, wherein the top surface of the second work function layer and the top surface of the first work function layer are higher than a top surface of the second dielectric layer.

6. The semiconductor structure of claim 4, wherein the gate dielectric layer extends to a sidewall of the insulating layer sequentially along a sidewall of the first dielectric layer and a sidewall of the second dielectric layer.

7. The semiconductor structure of claim 4, wherein the first work function layer has a portion between the second work function layer and the insulating layer.

8. The semiconductor structure of claim 4, wherein the first work function layer has a portion between the second work function layer and the second dielectric layer.

9. The semiconductor structure of claim 4, wherein the first work function layer has a portion between the second work function layer and the first dielectric layer.

10. The semiconductor structure of claim 4, wherein the array area of the substrate has a trench, and the second dielectric layer extends into the trench of the array area of the substrate.

11. The semiconductor structure of claim 10, wherein a depth of the recess the peripheral area of the substrate is less than a depth of the trench of the array area of the substrate.

12. The semiconductor structure of claim 10, wherein the array area of the substrate comprises a word line structure in the trench and surrounded by the second dielectric layer.

13. The semiconductor structure of claim 12, wherein the word line structure comprises a titanium nitride layer and a polysilicon layer above and aligned with the titanium nitride layer in a vertical direction.

14. A method of forming a semiconductor structure, comprising:
forming a recess in a peripheral area of a substrate;
forming a gate dielectric layer on a surface of the recess;
forming a first work function layer in the recess and on the gate dielectric layer; and
forming a second work function layer in the recess and on the first work function layer, wherein the first work function layer and the second work function layer define a gate structure, the second work function layer is surrounded by the first work function layer, the first work function layer is located between the second work function layer and the gate dielectric layer, and a work function of the first work function layer is different from a work function of the second work function layer.

15. The method of forming the semiconductor structure of claim 14, further comprising:
forming a first dielectric layer on a top surface of the substrate;
forming a second dielectric layer on the first dielectric layer; and
forming an insulating layer on the second dielectric layer.

16. The method of forming the semiconductor structure of claim 15, further comprising:
forming an oxide layer to cover the insulating layer; and
etching the oxide layer to form a remaining portion of the oxide layer on the insulating layer on the peripheral area of the substrate.

17. The method of forming the semiconductor structure of claim 16, further comprising:
forming a hard mask layer to cover the remaining portion of the oxide layer and the insulating layer;
etching back the hard mask layer to expose the remaining portion of the oxide layer;
etching the remaining portion of the oxide layer and the insulating layer below the remaining portion of the oxide layer to form an opening, wherein a portion of the substrate is exposed through the opening; and
removing the hard mask layer.

18. The method of forming the semiconductor structure of claim 17, wherein forming the recess in the peripheral area of the substrate comprises:
etching the portion of the substrate exposed through the opening by using the insulating layer as a mask.

19. The method of forming the semiconductor structure of claim 15, further comprising:
forming the gate dielectric layer on a sidewall of the first dielectric layer, a sidewall of the second dielectric layer, and a sidewall of the insulating layer;
forming the first work function layer on a top surface of the insulating layer and the gate dielectric layer that is on the sidewall of the first dielectric layer, the sidewall of the second dielectric layer, and the sidewall of the insulating layer; and
forming the second work function layer along the first work function layer.

20. The method of forming the semiconductor structure of claim 19, further comprising:
etching the second work function layer and the first work function layer in sequence to form the gate structure.
